(19) United States
(12) Patent Application Publication
(10) Pub. No.: US 2024/0213156 A1
(43) Pub. Date: Jun. 27, 2024

(54) LIQUID METAL WELLS FOR INTERCONNECT ARCHITECTURES

(71) Applicant: Intel Corporation, Santa Clara, CA (US)

(72) Inventors: Kristof DARMAWIKARTA, Chandler, AZ (US); Srinivas V. PIETAMBARAM, Chandler, AZ (US); Gang DUAN, Chandler, AZ (US); Tarek A. IBRAHIM, Mesa, AZ (US); Aaron GARELICK, Chandler, AZ (US); Srikant NEKKANTY, Chandler, AZ (US); Ravindranath V. MAHAJAN, Chandler, AZ (US); Rahul N. MANEPALLI, Chandler, AZ (US)

(21) Appl. No.: 18/089,491

(22) Filed: Dec. 27, 2022

(51) Int. Cl. H01L 23/532; H01L 23/00; H01L 23/15; H01L 23/498; H01L 23/522; H01L 23/535; H01L 23/64; H01L 25/065

(52) U.S. Cl. CPC H01L 23/53209; H01L 23/15; H01L 23/49816; H01L 23/5226; H01L 23/535; H01L 23/642; H01L 24/05; H01L 24/29; H01L 25/0655; H01L 2224/04026; H01L 2224/05567; H01L 2224/29007; H01L 2224/29021; H01L 2224/29101; H01L 2924/1436; H01L 2924/15321

(57) ABSTRACT

Embodiments disclosed herein include package substrates. In an embodiment, the package substrate comprises a core and buildup layers over the core. In an embodiment, a pad is provided on the buildup layers. In an embodiment, a liquid metal well is over the pad.

### TECHNICAL FIELD

Embodiments of the present disclosure relate to electronic packages, and more particularly to packaging architectures that include interconnects that leverage liquid metal wells for improved interconnection of components.

### BACKGROUND

In some packaging architectures, a mold layer with an embedded bridge couples together a pair of overlying dies. Direct electrical connections to the overlying dies may be made through conductive pillars that are embedded in the mold layer adjacent to the bridge. The use of such an architecture is not without issue. For example, plating nonuniformity of the conductive pillars can lead to challenges at via reveal and planarization operations. Due to the presence of a thermally insulating mold layer, thermal conductivity and warpage are also problems that can impact the complex attachment and/or bonding to an underlying substrate.

In some instances, liquid metal interconnects have been proposed for socket interconnects between substrates and board. Currently, the conductive liquid metal is deposited and housed in a separate epoxy-based frame that is subsequently attached at the end of the line (e.g., after top die attach). However, this poses many challenges due to handling of these thin frames and potential contamination of the liquid metal on the surface of the substrate. Accordingly, existing liquid metal solutions are not generally capable of being used for high volume manufacturing product lines.

### BRIEF DESCRIPTION OF THE DRAWINGS

FIG. 1A is a cross-sectional illustration of a multi-die module that includes a mold layer with liquid metal wells, in accordance with an embodiment.

FIG. 1B is a cross-sectional illustration of a multi-die module that is coupled to an underlying substrate using pins that are inserted into liquid metal wells of the multi-die module, in accordance with an embodiment.

FIG. 2 is a cross-sectional illustration of an electronic package that includes wells for liquid metal and a detachable component coupled to the liquid metal wells, in accordance with an embodiment.

FIG. 3A is a cross-sectional illustration of an electronic package that includes a package substrate with liquid metal wells, in accordance with an embodiment.

FIG. 3B is a cross-sectional illustration of an electronic package with a main die and component dies that are coupled to the package substrate through liquid metal connections, in accordance with an embodiment.

FIG. 4A is a cross-sectional illustration of an electronic package that includes a mold layer with liquid metal wells in the mold layer, in accordance with an embodiment.

FIG. 4B is a cross-sectional illustration of a package substrate that includes liquid metal wells in buildup layers of the package substrate, in accordance with an embodiment.

FIGS. 5A-5F are cross-sectional illustrations depicting a process of forming an electronic package with liquid metal wells, in accordance with an embodiment.

FIGS. 6A-6K are cross-sectional illustrations depicting a process for forming an electronic package with liquid metal wells in a mold layer, in accordance with an embodiment.

FIG. 7 is a schematic of a computing device built in accordance with an embodiment.

### EMBODIMENTS OF THE PRESENT DISCLOSURE

Described herein are packaging architectures that include interconnects that leverage liquid metal wells for improved interconnection of components, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, mold layers in multi-die modules can result in issues with assembly. For example, conductive pillars through the mold layer may be susceptible to non-uniform plating. This results in difficulties during via reveal and planarization processes. Accordingly, embodiments disclosed herein replace the conductive pillars in the mold layer with a liquid metal well. In such cases the underlying substrate may include pillars that are inserted into the liquid metal wells. The presence of the liquid metal allows for greater accommodation of non-uniform pillar heights. As such, bonding and assembly processes are improved.

Additionally, embodiments disclosed herein leverage the use of liquid metal architectures in order to improve coupling between dies, components, substrates, and the like. In a particular embodiment, the liquid metal is disposed in wells that can be fabricated directly into the package substrate. As such, there is no need for fragile epoxy frames and the like, and handling and assembly are simplified. In an embodiment, the liquid metal wells may be formed on either side of the package substrate. For example, liquid metal wells may be provided on the die side of the package substrate above the core or on the board side of the package substrate below the core. In some instances, the use of liquid metal interconnects allows for modular multichip packaging. That is, when a component needs to be changed (e.g., due to device failure, the need for a performance upgrade, or the like), the component may be easily removed without the need to remove solder interconnects.

As used herein, a liquid metal may refer to a material that is in the liquid phase or a liquid like composition at room temperature. The liquid metal may remain in a liquid phase or a liquid like composition down to temperatures of approximately 0 degrees Celsius or below. In an embodiment, the liquid metal may substantially comprise a conductive metal element. For example, the liquid metal may comprise one or both of gallium and indium. In other embodiments, the liquid metal may be a paste like material. In such embodiments, the liquid metal may have a polymer matrix that is filled with conductive particles. Though, it is to be appreciated that any conductive material that has flow characteristics similar to that of a liquid may be considered a liquid metal herein.

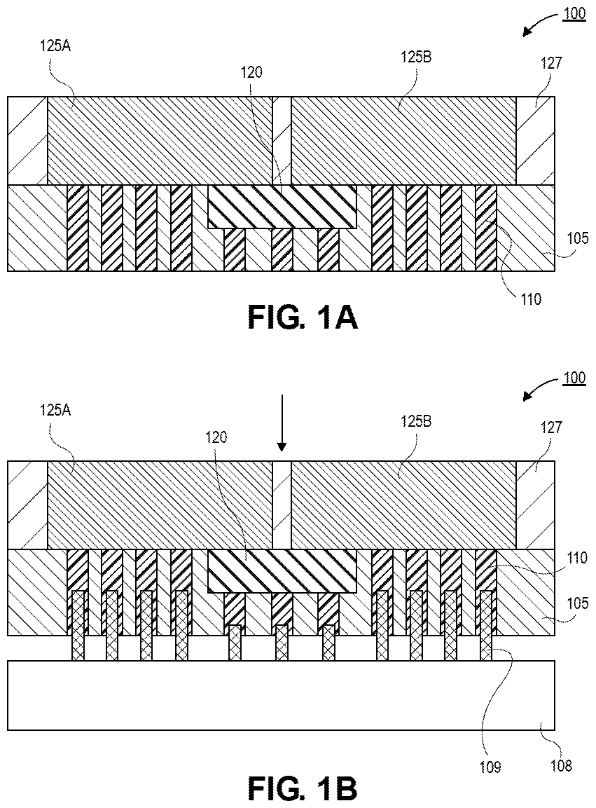

Referring now to FIG. 1A, a cross-sectional illustration of a multi-chip package 100 is shown, in accordance with an embodiment. In an embodiment, the package 100 may include a first die 125A and a second die 125B. The first die 125A may be laterally adjacent to the second die 125B. In an embodiment, the first die 125A and the second die 125B may be surrounded (or embedded) by a mold layer 127. Though, in other embodiments, the mold layer 127 may be omitted. The first die 125A and the second die 125B may be compute dies, such as processors, graphics processors, XPUs, SoCs, communication dies, or the like. One of the first die 125A and the second die 125B may also be a memory die.

In an embodiment, the first die 125A may be communicatively coupled to the second die 125B by a bridge die 120. The bridge die 120 may be embedded in a mold layer 105 below the first die 125A and the second die 125B. In an embodiment, the bridge die 120 may be a semiconductor material, such as silicon. Though, glass substrates may also be used for the bridge die 120 in some embodiments. The bridge die 120 may include high density routing in order to communicatively couple the first die 125A to the second die 125B. While shown as being in direct contact with the bridge die 120 for simplicity, it is to be appreciated that interconnects (e.g., first level interconnects (FLIs)) may be provided between the first die 125A and the bridge die 120, and between the second die 125B and the bridge die 120. FLIs may also be provided between the first die 125A and the mold layer 105, and between the second die 125B and the mold layer 105.

In contrast to existing solutions, direct connections to the first die 125A and the second die 125B through the mold layer 105 are made with liquid metal 110. The liquid metal 110 may be provided in wells through the mold layer 105. The wells may be high aspect ratio features. As used herein, high aspect ratio features may have a depth:width ratio that is approximately 3:1 or greater. For example, the wells may have aspect ratios of 3:1 or greater, 5:1 or greater, or 10:1 or greater. In an embodiment, the wells may have substantially vertical sidewalls. In other embodiments, the wells may have sloped sidewalls. In the illustrated embodiment, the wells are entirely filled by the liquid metal 110. In other embodiments, the wells may be partially filled by the liquid metal 110. Partial filling allows for pins to be inserted into the wells without overflowing the liquid metal 110 outside of the wells. The liquid metal 110 may be any liquid metal material such as those described in greater detail above. For example, the liquid metal 110 may comprise gallium and/or indium.

Referring now to FIG. 1B, a cross-sectional illustration of the multi-chip module 100 as it is being attached to an underlying substrate 108 is shown, in accordance with an embodiment. The underlying substrate 108 may be a package substrate. In other instances, the underlying substrate 108 may be a board, such as a printed circuit board (PCB). As shown, the substrate 108 may include a plurality of pillars or pins 109. The pins 109 may be conductive material, such as copper. Since the pins 109 are inserted into the liquid metal 110, greater plating nonuniformity of the pins 109 can be tolerated by the system. This eases the manufacturing complexity and can result in increased yields. In an embodiment, first pins 109 may be provided below the first die 125A and the second die 125B, and second pins 109 may be provided below the bridge die 120. The second pins 109 may be shorter than the first pins 109. As indicated by the arrow, the multi-chip package 100 may be displaced towards the substrate 108 in order to provide the connection between the components. More generally, an electrical connection may be provided between the first die 125A and the substrate 108 through the liquid metal 110 and the pins 109. Similar connections are provided between the second die 125B and the substrate 108, and between the bridge die 120 and the substrate 108.

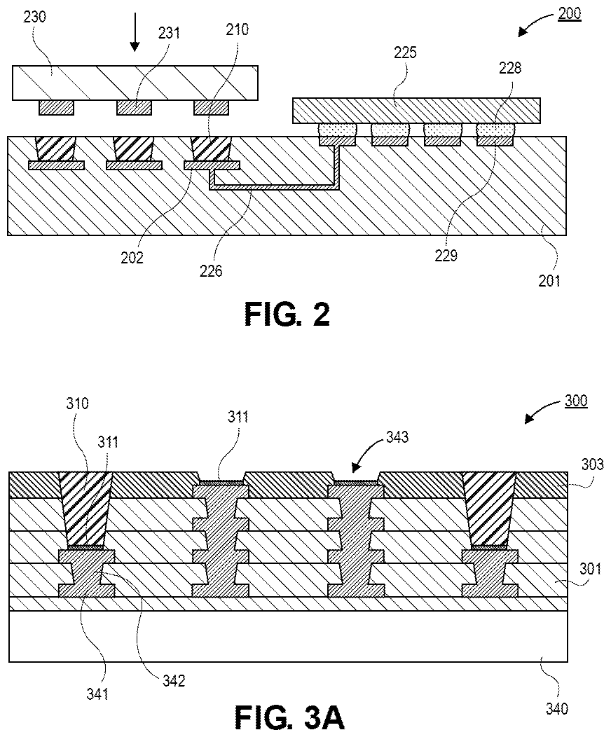

Referring now to FIG. 2, a cross-sectional illustration of an electronic package 200 is shown, in accordance with an embodiment. The electronic package 200 may comprise a package substrate 201. While shown as a monolithic structure, it is to be appreciated that the package substrate 201 may include a plurality of layers and a core in some embodiments. In an embodiment, a die 225 may be coupled to the package substrate 201. For example, interconnects 228 (e.g., FLIs) may be provided over pads 229. The die 225 may be any type of die. For example, the die 225 may be a processor, a graphics processor, an SoC, an ASIC, an XPU, or the like.

In an embodiment, a plurality of wells that are filled with liquid metal 210 may be provided into a surface of the package substrate 201. The wells may have sloped sidewalls or the sidewalls may be vertical. The shape of the wells may be dictated by the processing operations used to form the wells. In the illustrated embodiment, the wells are fully filled with liquid metal 210. Though in some embodiments, the liquid metal 210 may only partially fill the wells. The wells of liquid metal 210 may be provided over pads 202. The pads 202 may be electrically coupled to pads 229 through the package substrate 201 using conductive routing 226. The conductive routing 226 may include pads, traces, vias, and the like. The liquid metal 210 may be any liquid metal composition, such as those described in greater detail above. For example, the liquid metal 210 may comprise gallium and/or indium.

In an embodiment, a component 230 may be attached to the package substrate 201, as indicated by the arrow. The component 230 may be brought into contact with the package substrate 201 so that pillars 231 insert into the wells and are surrounded by the liquid metal 210. The use of a liquid metal 210 attachment allows for the component 230 to be a modular component 230. That is, the component 230 may be easily removed and replaced (e.g., when the component 230 is damaged, or upgraded components 230 are needed). In an embodiment, the component 230 may be a compute die, a passive device, a memory, or the like. In other embodiments, the component may be a separate electronic package that includes a die and a package substrate. In a particular embodiment, the component 230 may be a photonics module such as co-packaged optics.

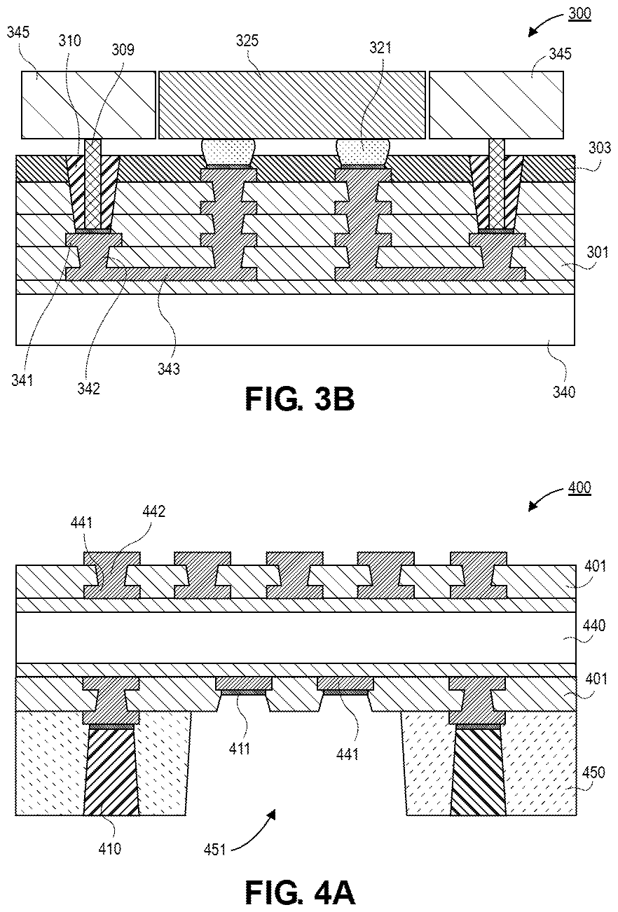

Referring now to FIG. 3A, a cross-sectional illustration of a package substrate 300 is shown, in accordance with an embodiment. In an embodiment, the package substrate 300 comprises a core 340. The core 340 may be a glass core 340 or an organic core 340. In an embodiment, buildup layers 301 may be provided above the core 340. While not shown for simplicity, buildup layers may also be provided below the core 340. The buildup layers 301 may be organic layers such as buildup film. In an embodiment, conductive routing may be provided in the buildup layers 301. For examples, pads 341, vias 342, and traces (not shown) may be provided in the buildup layers 301.

In the illustrated embodiment, two pads 341 are provided at the top of the buildup layers 301. Solder resist openings 343 may be provided through a solder resist 303 in order to expose the pads 341. Additionally, pads 341 may be embedded in the buildup layers 301. The embedded pads 341 may be contacted by liquid metal 310 that is provided in wells through the package substrate 300. For example, the wells may pass through one or more buildup layers 301 and the solder resist 303.

In an embodiment, surface finishes 311 may be provided over the pads 341. The surface finish may be any suitable surface finish 311 common in semiconductor packaging industries. For example, the surface finish 311 may comprise one or more of nickel, gold, palladium, and the like.

Referring now to FIG. 3B, a cross-sectional illustration of the package substrate 300 after components are attached is shown, in accordance with an embodiment. As shown, a die 325 may be coupled to the pads 341 at the top of the buildup layers 301 using interconnects 321. The interconnects 321 may be any suitable FLI architecture. In an embodiment, the die 325 may be a compute die, such as a processor, a graphics processor, an XPU, an SoC, an ASIC, a communication die, or the like.

In an embodiment additional components 345 may be mounted to the package substrate 300. The additional components 345 may comprise pins or pillars 309. The pillars 309 may be high aspect ratio features that are inserted into the wells of liquid metal 310. The components 345 are electrically coupled to the embedded pads 341 by the combination of the liquid metal 310 and the pillars 309. The additional components 345 may include a package substrate and a die. In other embodiments, the additional components 345 may be a die only. The additional components 345 may also include passive devices, such as capacitors, inductors, or the like. The components 345 may be communicatively coupled to the die 325 through conductive routing in the package substrate 300. For example, pads 341, vias 342, and traces 343 may couple the components 345 to the die 325.

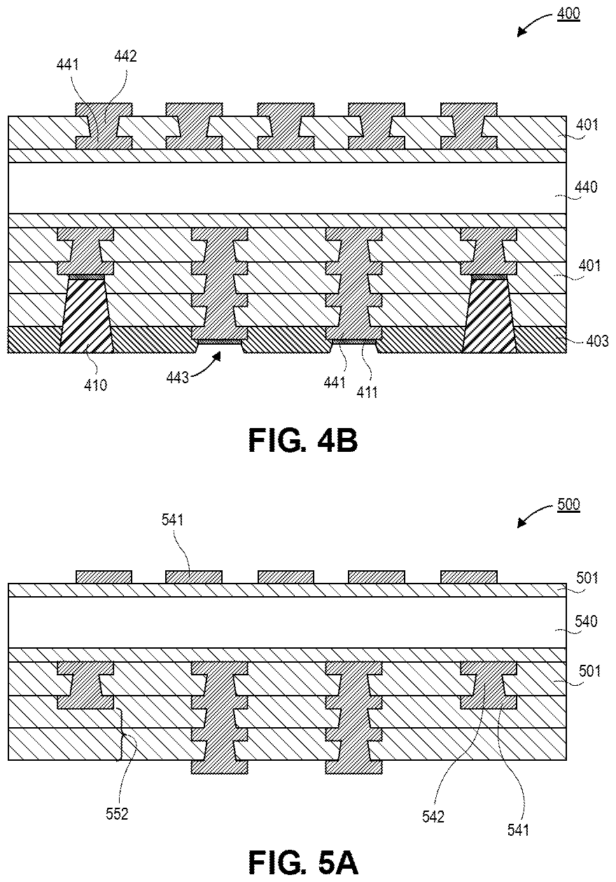

Referring now to FIG. 4A, a cross-sectional illustration of a package substrate 400 is shown, in accordance with an embodiment. In an embodiment, the package substrate 400 comprises a core 440, such as a glass core 440 or an organic core 440. Buildup layers 401 may be provided above and below the core 440. In an embodiment, pads 441, vias 442, traces (not shown), and other conductive features may be provided on and/or in the buildup layers 401 of the package substrate 400. In an embodiment, a mold layer 450 may be provided over a backside surface of the core 440. The mold layer 450 may be an epoxy or any suitable molding material. In an embodiment, the mold layer 450 may include an opening 451 to expose a set of pads 441 on the backside surface of the package substrate 400. The opening 451 may be sized to receive one or more components, such as a passive component (e.g., a capacitor). In an embodiment, the exposed pads 441 may include a surface finish 411.

In an embodiment, wells comprising liquid metal 410 may be provided through the mold layer 450. The liquid metal 410 may be electrically coupled to pads 441 on the backside of the package substrate 400. A surface finish 411 may be provided between the liquid metal 410 and the pads 441. The well may have sidewalls that are sloped in some embodiments. The liquid metal 410 may be any suitable liquid metal composition. For example, the liquid metal 410 may comprise gallium and/or indium. In the illustrated embodiment, the liquid metal 410 fully fills the wells. Though, in other embodiments, the liquid metal 410 may partially fill the wells.

Referring now to FIG. 4B, a cross-sectional illustration of a package substrate 400 is shown, in accordance with an additional embodiment. The package substrate 400 in FIG. 4B may be substantially similar to the package substrate 400 in FIG. 4A, with the exception of the mold layer 450 being removed. Instead, wells of liquid metal 410 are formed through solder resist layer 403 and buildup layers 401. The wells may include sloped sidewalls. In an embodiment, the wells may pass through one or more buildup layers 401. For example, the wells in FIG. 4B pass, at least partially, through a pair of buildup layers 401. Additionally, the center pads 441 may be exposed through solder resist openings 443. Instead of being recessed in a cavity, the center pads 441 are provided at the bottom surface of the package substrate 400.

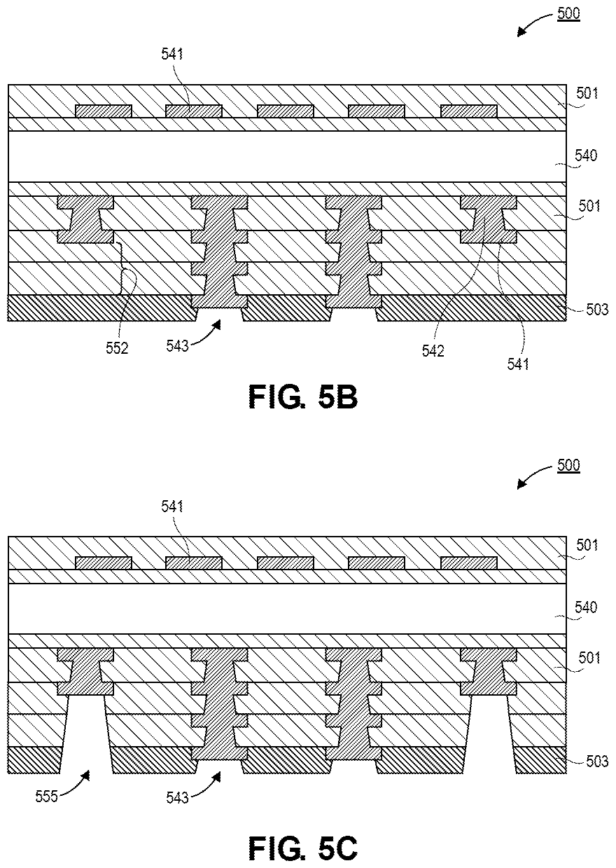

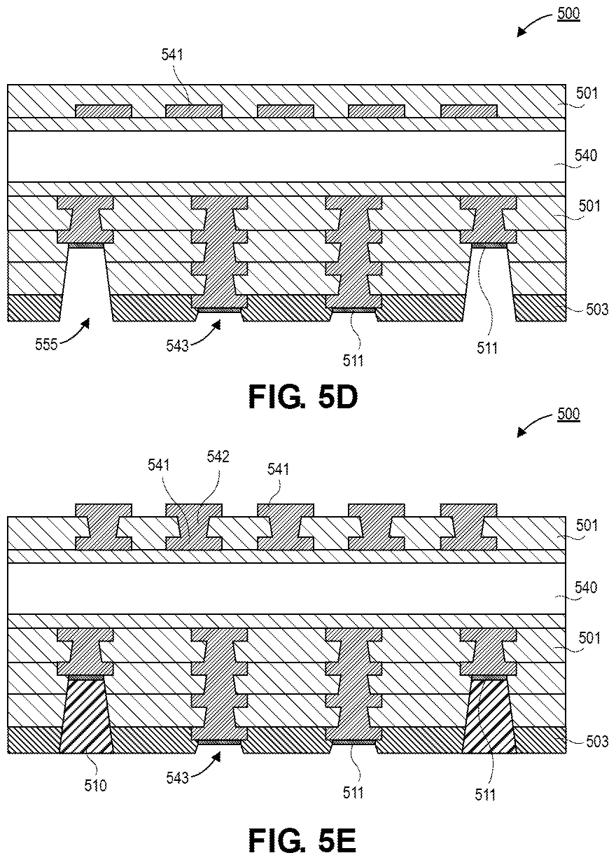

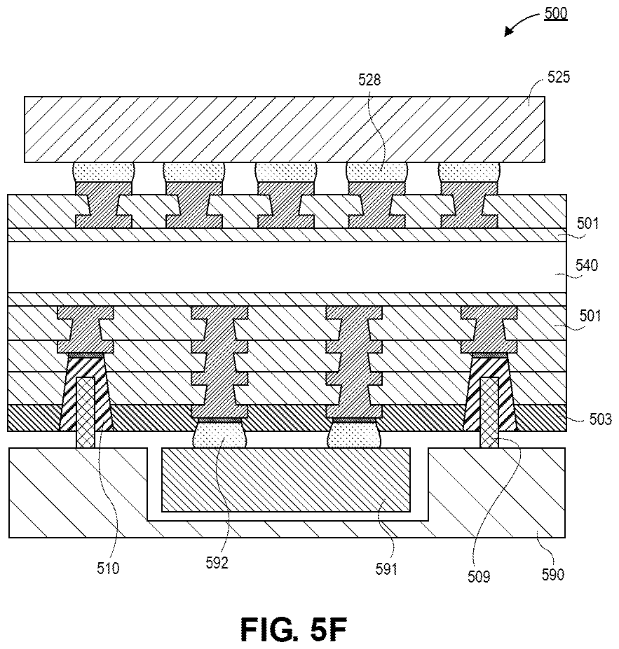

Referring now to FIGS. 5A-5F, a series of cross-sectional illustrations depicting a process for forming a package substrate 500 is shown, in accordance with an embodiment. In an embodiment, the package substrate 500 is similar to the package substrate 400 shown in FIG. 4B.

Referring now to FIG. 5A, a cross-sectional illustration of a package substrate 500 is shown, in accordance with an embodiment. The package substrate 500 may comprise a core 540. The core 540 may be a glass core 540 or an organic core 540. In an embodiment, buildup layers 501 may be provided over and under the core 540. The buildup layers 501 may be buildup film or the like. In an embodiment, pads 541, vias 542, traces (not shown), and other conductive features may be provided on and/or in the buildup layers 501 of the package substrate 500.

In an embodiment, a voided region 552 may be provided over one or more pads 541. The voided region 552 may be a volume of the buildup layers 501 that is free from electrical routing (e.g., pads 541, traces, vias 542, etc.). In the illustrated embodiment, the voided region 552 is provided in two buildup layers 501. Though, in other embodiments, the voided region 552 may be provided in one or more buildup layers 501. Voided regions are provided at locations where wells of liquid metal are desired.

Referring now to FIG. 5B, a cross-sectional illustration of the package substrate 500 after additional layers are provided over the package substrate 500. On the top side of the package substrate 500, an additional buildup layer 501 is provided over the pads 541. On the backside of the package substrate 500 a solder resist 503 is applied over the bottommost buildup layer 501. The solder resist 503 may be patterned to form solder resist openings 543 over pads 541.

Referring now to FIG. 5C, a cross-sectional illustration of the package substrate 500 after wells 555 are formed into the package substrate 500 is shown, in accordance with an embodiment. In an embodiment, the wells 555 may pass through the solder resist 503 and through one or more buildup layers 501. In the illustrated embodiment, the wells 555 pass, at least partially, through a pair of buildup layers. The wells 555 are provided in the voided regions 552 of the package substrate 500. In an embodiment, the wells 555 may have sloped sidewalls. For example, a width of the well 555 at the bottom of the package substrate 500 may be wider than a width of the well 555 at the pad 541. Though, in some embodiments, the wells 555 may have substantially vertical sidewalls. In an embodiment, the wells 555 may be formed with any suitable patterning process. In one instance, the wells 555 are formed with a laser ablation process. In other embodiments, the wells 555 are formed with a chemical etching process, a dry etching process (e.g., a plasma etching process), or the like.

Referring now to FIG. 5D, a cross-sectional illustration of the package substrate 500 after a surface finish 511 is applied to exposed pads 541 is shown, in accordance with an embodiment. In an embodiment, the surface finish 511 may include nickel, gold, palladium, or the like. The surface finish 511 may be applied with any suitable deposition process. Since only a portion of the pads 541 are exposed, the entire bottom surface of the pads 541 may not be covered by the surface finish 511.

Referring now to FIG. 5E, a cross-sectional illustration of the package substrate 500 after liquid metal 510 is dispensed in the wells 555 is shown, in accordance with an embodiment. The liquid metal 510 may be inserted into the wells 555 using any suitable process, such as a compression molding process or the like. In the illustrated embodiment, the liquid metal 510 completely fills the wells 555. Though, in some embodiments, the liquid metal 510 may partially fill the wells 555. The liquid metal 510 may be any liquid metal composition, such as those described in greater detail above. For example, the liquid metal 510 may comprise gallium and/or indium. Also shown in FIG. 5E is the completion of routing layers above the core 540. For example, vias 542 and pads 541 are provided through and over, respectively, a second buildup layer 501.

Referring now to FIG. 5F, a cross-sectional illustration of the package substrate 500 after components are attached is shown, in accordance with an embodiment. The top side of the package substrate 500 may receive a die 525. The die 525 may be coupled to the pads 541 by interconnects 528, such as FLIs. In an embodiment, the die 525 may be a compute die. Additionally, while a single die 525 is shown, it is to be appreciated that two or more dies 525 may also be attached to the top side of the package substrate 500 in some embodiments.

A component 591 may be attached to the backside of the package substrate 500. For example, interconnects 592 such as solder balls may connect the component 591 to the pads 541. In an embodiment, the component 591 may be a passive component, such as a capacitor, an inductor, or the like. The component 591 may also comprise a die in some instances.

In an embodiment, a substrate 590 may be coupled to the package substrate 500 as well. The substrate 590 may include pillars 509 that extend into the liquid metal 510 wells. The pillars 509 may be copper pillars or any other suitable conductive material. The pillars 509 may be high aspect ratio features. For example, the pillars 509 may have an aspect ratio of 3:1 or greater, 5:1 or greater, or 10:1 or greater. In an embodiment, each pillar 509 may be inserted into a different well 555, so that there is a 1:1 ratio of pillars 509 to wells 555. In other embodiments, multiple pillars 509 may be provided in a single well 555. Such embodiments may be particularly beneficial for power delivery applications.

In an embodiment, the substrate 590 may be a board, such as a PCB. Though, the substrate 590 may also be an additional package substrate, an interposer, or the like. In an embodiment, the substrate 590 may comprise a recess in order to accommodate the standoff height of the component 591. In other embodiments, the substrate 590 may comprise a hole that passes through an entire thickness of the substrate 590 in order to accommodate the standoff height of the component 591.

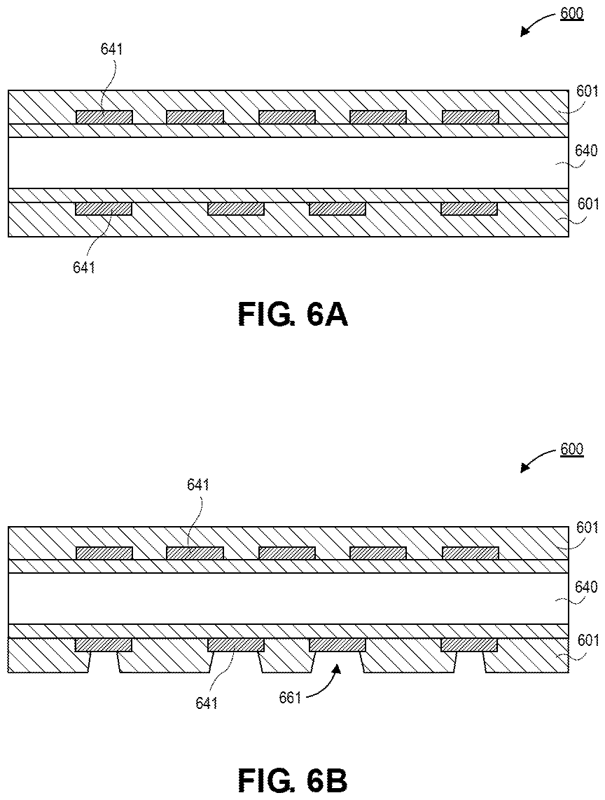

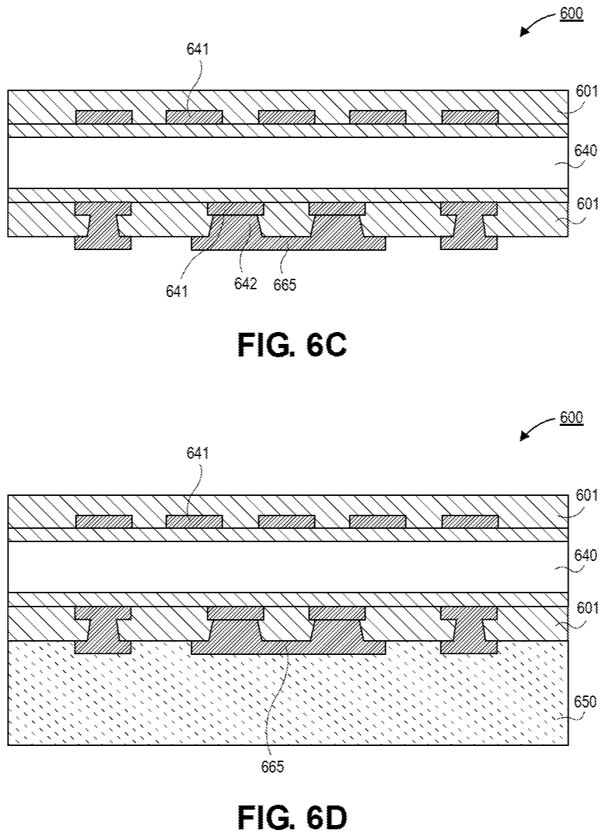

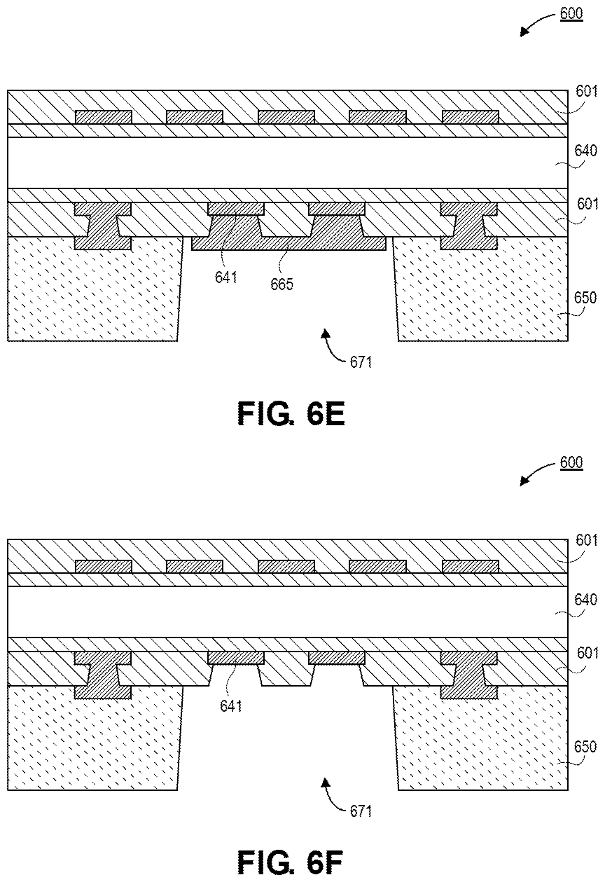

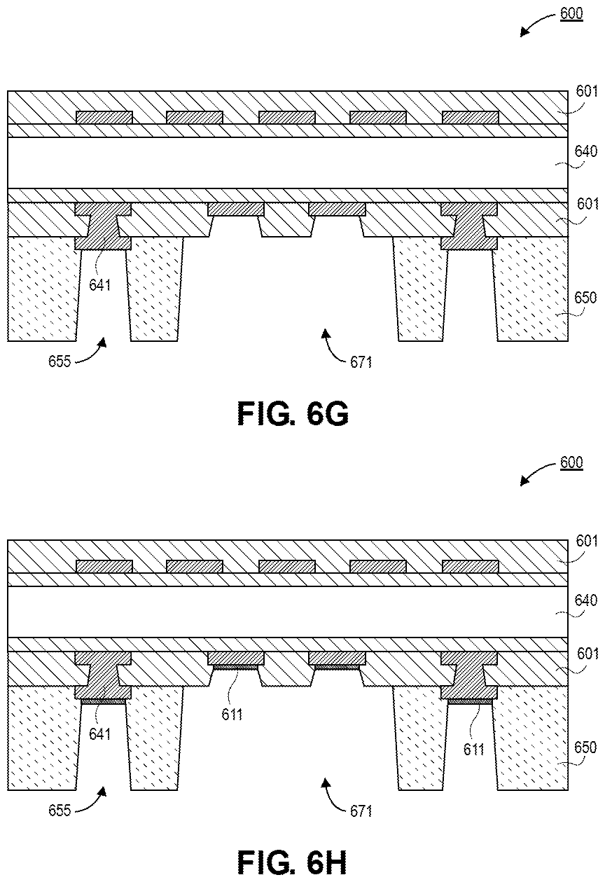

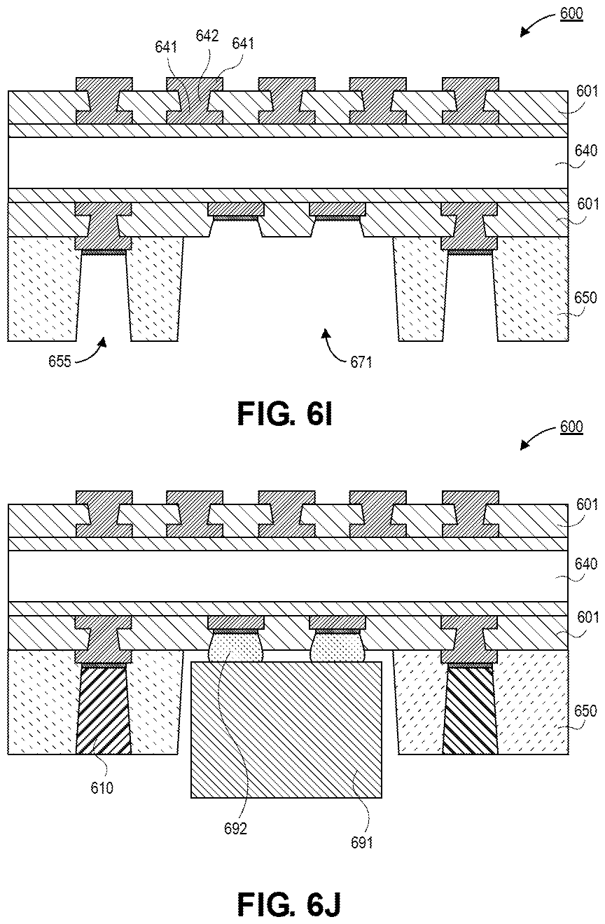

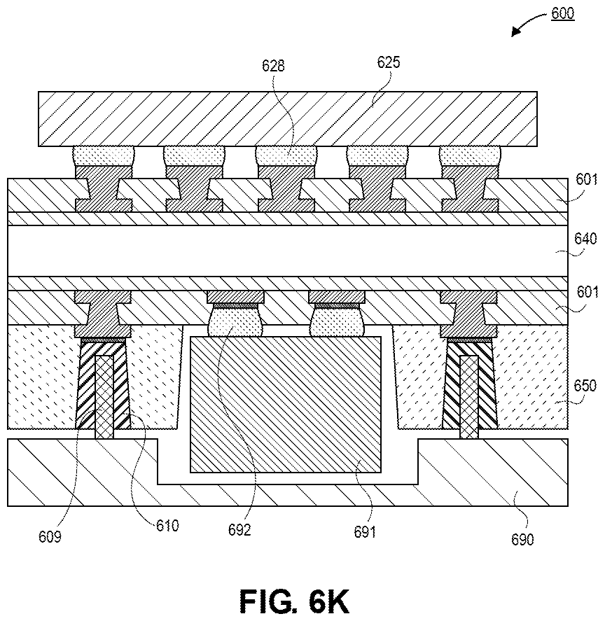

Referring now to FIGS. 6A-6K, a series of cross-sectional illustrations depicting a process for forming a package substrate 600 is shown, in accordance with an embodiment. The package substrate 600 may be substantially similar to the package substrate 400 described above with respect to FIG. 4A.

Referring now to FIG. 6A, a cross-sectional illustration of a package substrate 600 at a stage of manufacture is shown, in accordance with an embodiment. In an embodiment, the package substrate 600 comprises a core 640, such as a glass core 640 or an organic core 640. Buildup layers 601 may be provided over and under the core 640. In an embodiment, conductive routing may be embedded in the buildup layers 601. For example, pads 641 are shown in FIG. 6A.

Referring now to FIG. 6B, a cross-sectional illustration of the package substrate 600 after openings 661 are formed into the buildup layer 601 is shown, in accordance with an embodiment. As shown, the openings 661 expose surfaces of the pads 641. The openings 661 may be formed with a laser ablation process, or any other suitable patterning process. The sidewalls of the openings 661 may be sloped in some embodiments.

Referring now to FIG. 6C, a cross-sectional illustration of the package substrate 600 after features are plated on the backside buildup layers 601 is shown, in accordance with an embodiment. For example, vias 642 may be formed in the openings 661 and pads 641 may be provided over the vias 642. An etchstop layer 665 may also be plated over the surface of the buildup layers 601 in some embodiments.

Referring now to FIG. 6D, a cross-sectional illustration of the package substrate 600 after a mold layer 650 is applied is shown, in accordance with an embodiment. The mold layer 650 may be applied over the backside surface of the package substrate 600. In an embodiment, the mold layer 650 may be an epoxy material, or any other suitable molding compound.

Referring now to FIG. 6E, a cross-sectional illustration of the package substrate 600 after a cavity 671 is formed through the mold layer 650 is shown, in accordance with an embodiment. The cavity 671 may pass entirely through the mold layer 650 and expose the etchstop layer 665. The cavity 671 may be formed with any suitable patterning process, such as laser ablation, chemical etching, or the like. The sidewalls of the cavity 671 may be sloped in some embodiments.

Referring now to FIG. 6F, a cross-sectional illustration of the package substrate 600 after the etchstop layer 665 and the vias 642 are removed from the bottom of the cavity 671 is shown, in accordance with an embodiment. The etchstop layer 665 and the vias 642 may be removed with a chemical etching process, such as a wet etching process. The etch may be a timed etch so that underlying pads 641 remain intact.

Referring now to FIG. 6G, a cross-sectional illustration of the package substrate 600 after the wells 655 are formed is shown, in accordance with an embodiment. In an embodiment, the wells 655 may be provided over one or more pads 641. The wells 655 may pass substantially through a thickness of the mold layer 650 to expose the underlying pads 641. The wells 655 may be formed with any suitable patterning process, such as laser ablation, chemical etching, or the like. In some instances, the sidewalls of the wells 655 may be sloped.

Referring now to FIG. 6H, a cross-sectional illustration of the package substrate 600 after surface finishes 611 are applied over the exposed pads 641 is shown, in accordance with an embodiment. The surface finish 611 may include any surface finish common in semiconductor packaging applications. For example, the surface finish 611 may include one or more of nickel, gold, palladium, and the like.

Referring now to FIG. 6I, a cross-sectional illustration of the package substrate 600 after front side interconnect structures are completed is shown, in accordance with an embodiment. As shown, vias 642 and pads 641 may be provided through and over an additional buildup layer 601.

Referring now to FIG. 6J, a cross-sectional illustration of the package substrate 600 after liquid metal 610 is applied in the wells 655 and a component 691 is attached is shown, in accordance with an embodiment. The liquid metal 610 may be inserted into the wells 655 with any suitable deposition process, such as compression molding or the like. While shown as being fully filled, it is to be appreciated that the liquid metal 610 may partially fill the wells 655 in some embodiments. The liquid metal 610 may comprise any liquid metal composition, such as those described in greater detail above. For example, the liquid metal 610 may comprise gallium and/or indium. The component 691 may be a passive component, such as a capacitor, an inductor, or the like. The component 691 may be coupled to the package substrate 600 through interconnects 692, such as solder balls or the like.

Referring now to FIG. 6K, a cross-sectional illustration of the package substrate 600 after a die 625 is attached is shown, in accordance with an embodiment. In an embodiment, the die 625 may be attached to the package substrate 600 by interconnects 628 that are any FLI architecture. The die 625 may be a compute die. While a single die 625 is shown, it is to be appreciated that any number of dies 625 may be coupled to the package substrate 600.

In an embodiment, a substrate 690 may be attached to the bottom side of the package substrate 600. The substrate 690 may be a board, such as a PCB. The substrate 690 may alternatively be another package substrate, an interposer, or the like. In an embodiment, the substrate 690 may include pillars 609 that insert into the wells of liquid metal 610. The pillars 609 may be copper pillars 609 or any other conductive material. The pillars 609 may be high aspect ratio features (e.g., 3:1 or greater, 5:1 or greater, or 10:1 or greater). In an embodiment, each pillar 609 may be inserted into a different well 655, so that there is a 1:1 ratio of pillars 609 to wells 655. In other embodiments, multiple pillars 609 may be provided in a single well 655. Such embodiments may be particularly beneficial for power delivery applications. The substrate 690 may have a recess to accommodate a thickness of the component 691 that extends out past the mold layer 650. In some instances the substrate 690 may include a hole to accommodate the thickness of the component 691.

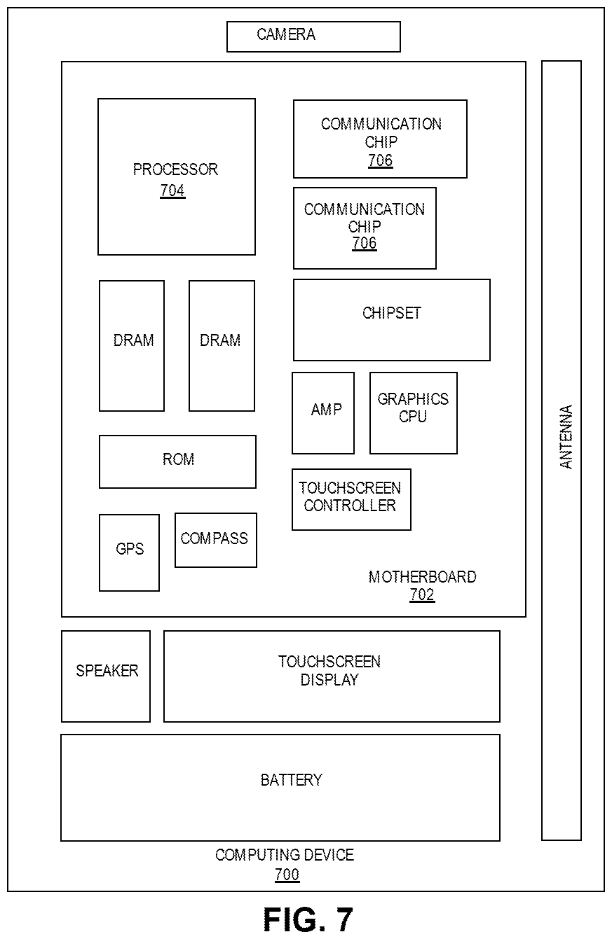

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package that comprises one or more interconnect solutions that include a liquid metal in a well in the electronic package, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of an electronic package that comprises one or more interconnect solutions that include a liquid metal in a well in the electronic package, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a core; buildup layers over the core; a pad on the buildup layers; and a liquid metal well over the pad.

Example 2: the package substrate of Example 1, further comprising: a mold layer over the buildup layers, wherein the liquid metal well is provided through the mold layer.

Example 3: the package substrate of Example 1 or Example 2, wherein the liquid metal well passes through one or more of the buildup layers.

Example 4: the package substrate of Examples 1-3, wherein the liquid metal well includes sloped sidewalls.

Example 5: the package substrate of Examples 1-4, wherein the core comprises glass.

Example 6: the package substrate of Examples 1-4, further comprising: a

surface finish over the pad.

Example 7: the package substrate of Examples 1-5, wherein the liquid metal

comprises gallium and/or indium.

Example 8: the package substrate of Examples 1-7, further comprising: a land side capacitor coupled to the buildup layers.

Example 9: the package substrate of Example 8, wherein the land side capacitor is provided in a mold layer over the buildup layers.

Example 10: the package substrate of Examples 1-9, further comprising: a board coupled to the package substrate, wherein the board comprises a pin that is inserted into the liquid metal well.

Example 11: the package substrate of Example 10, wherein the board is part of a computing system for a mobile device, a tablet, an automobile, a personal computer, or a server.

Example 12: a computing system, comprising: a package substrate; a die coupled to the package substrate; a well in the package substrate, wherein the well is at least partially filled by a liquid metal; and a component coupled to the package substrate, wherein the component includes a post that is inserted into the well.

Example 13: the computing system of Example 12, wherein the component is electrically coupled to the die through the package substrate.

Example 14: the computing system of Example 12 or Example 13, wherein the die is a processor, and wherein the component comprises co-packaged optics.

Example 15: the computing system of Examples 12-14, wherein the liquid metal comprises gallium and/or indium.

Example 16: the computing system of Examples 12-15, wherein the component is a second die.

Example 17: the computing system of Example 16, wherein the second die comprises a memory die.

Example 18: a computing system, comprising: a mold layer; a first die over the mold layer; a second die over the mold layer and adjacent to the first die; a bridge die in the mold layer, wherein the bridge die communicatively couples the first die to the second die; and wells into the mold layer, wherein the wells are at least partially filled with a liquid metal.

Example 19: the computing system of Example 18, further comprising: a board coupled to the mold layer, wherein posts of the board are inserted into the wells into the mold layer.

Example 20: the computing system of Example 18 or Example 19, wherein the computing system is part of a mobile device, a tablet, an automobile, a personal computer, or a server.

What is claimed is:

1. A package substrate, comprising:
a core;
buildup layers over the core;
a pad on the buildup layers; and
a liquid metal well over the pad.

2. The package substrate of claim 1, further comprising:
a mold layer over the buildup layers, wherein the liquid metal well is provided through the mold layer.

3. The package substrate of claim 1, wherein the liquid metal well passes through one or more of the buildup layers.

4. The package substrate of claim 1, wherein the liquid metal well includes sloped sidewalls.

5. The package substrate of claim 1, wherein the core comprises glass.

6. The package substrate of claim 1, further comprising:
a surface finish over the pad.

7. The package substrate of claim 1, wherein the liquid metal comprises gallium and/or indium.

8. The package substrate of claim 1, further comprising:
a land side capacitor coupled to the buildup layers.

9. The package substrate of claim 8, wherein the land side capacitor is provided in a mold layer over the buildup layers.

10. The package substrate of claim 1, further comprising:
a board coupled to the package substrate, wherein the board comprises a pin that is inserted into the liquid metal well.

11. The package substrate of claim 10, wherein the board is part of a computing system for a mobile device, a tablet, an automobile, a personal computer, or a server.

12. A computing system, comprising:
a package substrate;
a die coupled to the package substrate;
a well in the package substrate, wherein the well is at least partially filled by a liquid metal; and
a component coupled to the package substrate, wherein the component includes a post that is inserted into the well.

13. The computing system of claim 12, wherein the component is electrically coupled to the die through the package substrate.

14. The computing system of claim 12, wherein the die is a processor, and wherein the component comprises co-packaged optics.

15. The computing system of claim 12, wherein the liquid metal comprises gallium and/or indium.

16. The computing system of claim 12, wherein the component is a second die.

17. The computing system of claim 16, wherein the second die comprises a memory die.

18. A computing system, comprising:
a mold layer;
a first die over the mold layer;
a second die over the mold layer and adjacent to the first die;
a bridge die in the mold layer, wherein the bridge die communicatively couples the first die to the second die; and
wells into the mold layer, wherein the wells are at least partially filled with a liquid metal.

19. The computing system of claim 18, further comprising:
a board coupled to the mold layer, wherein posts of the board are inserted into the wells into the mold layer.

20. The computing system of claim 19, wherein the computing system is part of a mobile device, a tablet, an automobile, a personal computer, or a server.
